(19) United States
(12) Patent Application Publication
(10) Pub. No.: US 2024/0418814 A1
(43) Pub. Date: Dec. 19, 2024

(54) SYSTEM AND METHOD FOR DETERMINING DATA QUALITY USING K-SPACE MAGNETIC RESONANCE IMAGING DATA

(71) Applicant: NOUS Imaging, Inc., St. Louis, MO (US)

(72) Inventor: Nico Dosenbach, St. Louis, MO (US)

(21) Appl. No.: 18/262,865

(22) PCT Filed: Jan. 24, 2022
(86) PCT No.: PCT/US2022/013548

§ 371 Date: Jul. 25, 2023

Related U.S. Application Data
(60) Provisional application No. 63/141,253, filed on Jan. 25, 2021.

(51) Int. Cl. G01R 33/565; G01R 33/567

(52) U.S. Cl. CPC G01R 33/56509; G01R 33/5673

(57) ABSTRACT

Systems and methods are provided for managing the acquisition of MRI k-space data to reduce artifacts caused by degraded data quality and scan times required to acquire all necessary data at the requisite data quality. MRI k-space data may include any form of raw MR data acquired with an MRI system, including functional MRI (fMRI) data, resting state fMRI (rs-fMRI) data, per-fusion-weighted data, and other MRI data. Real-time monitoring and prediction of degraded data quality may be used, such as monitoring patient motion during scanning.

### CROSS-REFERENCE TO RELATED APPLICATIONS

This application claims the benefit of U.S. Provisional Patent Application Ser. No. 63/141,253 filed on Jan. 25, 2021 and entitled “System and Method for Determining Data Quality Using k-Space Magnetic Resonance Imaging Data,” which is incorporated herein by reference as if set forth in its entirety for all purposes.

### STATEMENT REGARDING FEDERALLY SPONSORED RESEARCH

N/A

### BACKGROUND

Patient motion of any kind (whether bulk rigid motion, or complex deformative motion) represents one of the greatest obstacles to preforming medical imaging in many clinical applications. Some clinical applications require the precise acquisition of small signals with high spatial resolution, such that even small amounts of motion can substantially damage the clinical value of the information. For example, magnetic resonance imagining (MRI) of the brain represents a highly valuable clinical application that is very susceptible to damaging the clinical value of the images with even small amounts of motion. For example, head motion damages the value of anatomical or structural (T1-weighted, T2-weighted, etc.) images and can be even more damaging to the clinical utility of so-called functional MRI data (fMRI). Even sub-millimeter head movements (e.g., micro-movements) may systematically alter structural and functional MRI data in some cases. Hence, much effort has been devoted towards developing post-acquisition methods for the removal of head motion distortions from MRI data.

Head movement from one MRI data frame to the next, rather than absolute movement away from the reference frame, is thought to induce the most significant MRI signal distortions. Motion-related distortions are strongly correlated with measures of framewise displacement (FD), which represent the sum of the absolute head movements in all six rigid body directions from frame to frame, as well as DVARS, which is the root mean square of the derivatives of the differentiated time courses of every voxel of an MRI image. Thus, measures such as FD and DVARS that capture the global effects of movement of the subject during MRI data acquisition, have been used to assess data quality in various post-hoc methods. For example, post-hoc frame censoring to remove all MRI data frames with FD values above a certain threshold (for example, excluding data frames with FD values >0.2 mm) has become a commonly used method for improving functional MRI data quality.

Though necessary for reducing artifacts, frame censoring comes at a steep price. For example, frame censoring can exclude 50% or more of the data in some studies. For example, so-called resting-state functional-connectivity MRI (rs-fcMRI) data can be particularly susceptible to motion issues, because the studies, by definition, are extensive in length and focused on small signals elicited by the blood oxygen level dependent (BOLD) contrast mechanism. Because the accuracy of MRI measures improves as the number of frames increases, a minimum number of data frames may be required to obtain reliable data. If the number of frames remaining after censoring is too small, investigators may lose all data from a patient. In order to avoid this loss, clinicians typically collect additional “buffer” data, an expensive practice that, by itself, does not guarantee sufficient high-quality MRI data for a given participant. The overscanning required to remove motion-distorted data, while maintaining sample sizes adequate to achieve a desired data quality, has drastically increased the cost and duration of brain MRIs. Of course, in some ways the solution only exacerbates the problem. That is, the likelihood of patient motion increases with scan duration, so extending the scan to collect additional data only increases the likelihood of patient motion.

Recently developed structural MRI sequences with prospective motion correction use a similar approach to reduce the deleterious effects of head motion. These MRI sequences pair each structural data acquisition with a fast, low resolution, snap shot of the whole brain (e.g., echo-planar image, EPI) acquisition, which is then used as a marker or navigator for head motion. These motion-correcting structural sequences calculate relative motion between successive navigator images and use this information to mark the linked structural data frames for exclusion and reacquisition. In this manner, structural data frames are ‘censored,’ thereby increasing the duration and cost of structural MRIs.

These challenges with motion correction in the general context of MRI are substantial. The need to reconstruct an image prior to performing motion correction also requires bespoke correction methods for each separate scanner platform or manufacturer given differences in how reconstruction is performed by each manufacturer. As such, not only does motion represent an impediment to the creation of important clinical images, but the tools to combat motion are varied and typically specific to a given manufacturer of the particular MRI system being utilized, if not also specific to the particular clinical application being performed. Of course, proprietary tools and tools specific to a particular clinical application impede consistency of care and repeatability of results because the wide number of systems and solutions makes every study nearly unique.

### SUMMARY OF THE DISCLOSURE

The present disclosure recognizes that patient motion is just one example of a variety of causes for degradation of data quality and, thus, image quality in magnetic resonance imaging. The present disclosure provides systems and methods to address the aforementioned drawbacks and many others by providing systems and methods for determining data quality of data acquired during a magnetic resonance imaging (MRI) procedure using MRI k-space data. Detecting or even predicting motion of the subject or other impediments to data quality may be performed in real-time during the MRI procedure. Real-time monitoring of data quality with feedback to an MRI operator or to the subject may also provide for mitigating the cause of negative data quality.

In one aspect, a computer-implemented method is provided for identifying decreases in data quality during a magnetic resonance imaging (MRI) study. The method includes receiving, by a computing system that includes at least one processor in communication with at least one memory system and that is in communication to receive data acquired using a magnetic resonance imaging (MRI) system, k-space data acquired by the MRI system while performing an MRI study. The method also includes analyzing, by the computing system, the received k-space data to identify signs of decreased data quality in the k-space data. The method also includes displaying, by the computing system, a real-time indication to an operator of the MRI system during the MRI study, a report indicating the decreased data quality and at least one of an amount of k-space data affected by the decreased data quality or an amount of the MRI study to be repeated due to amount of k-space data affected by the decreased data quality.

In one aspect, a computer-implemented method is provided for identifying decreases in data quality during a magnetic resonance imaging (MRI) study. The method includes receiving, by a computing system that includes at least one processor in communication with at least one memory system and that is in communication to receive data acquired using a magnetic resonance imaging (MRI) system, k-space data acquired by the MRI system while performing an MRI study. The method also includes analyzing, by the computing system, the received k-space data to identify signs of decreased data quality in the k-space data. The method also includes and displaying, by the computing system, a report indicating decreased data quality in the k-space data based on the analyzing of the received k-space data.

In one aspect, a magnetic resonance imaging system (MRI) configured for identifying decreases in data quality during a magnetic resonance imaging (MRI) study is provided. The system includes a computing system that includes at least one processor in communication with at least one memory system and that is in communication to receive k-space data acquired using the MRI system while performing an MRI study. The computing system is configured to: i) analyze the received k-space data to identify signs of decreased data quality in the k-space data; and ii) display a real-time indication to an operator of the MRI system during the MRI study, a report indicating the decreased data quality and at least one of an amount of k-space data affected by the decreased data quality or an amount of the MRI study to be repeated due to amount of k-space data affected by the decreased data quality.

The foregoing and other aspects and advantages of the present disclosure will appear from the following description. In the description, reference is made to the accompanying drawings that form a part hereof, and in which there is shown by way of illustration a preferred embodiment. This embodiment does not necessarily represent the full scope of the invention, however, and reference is therefore made to the claims and herein for interpreting the scope of the invention. Like reference numerals will be used to refer to like parts from Figure to Figure in the following description.

### BRIEF DESCRIPTION OF THE DRAWINGS

FIG. 1A is a flowchart of a non-limiting example of a method for processing a set of k-space datasets to compensate for a subjects' movement.

FIG. 1B is a non-limiting example block diagram of a system for processing a set of k-space MRI datasets to compensate for a subjects' movement, is shown

FIG. 2 is a flowchart illustrating a non-limiting example method for providing a sensory feedback to the operator of the MRI system and/or the patient within the MRI system during data acquisition.

FIG. 3 is a flowchart illustrating a non-limiting example method for removing artifacts associated with detected motion data using an Nth order filter.

FIG. 4 is a flowchart illustrating a non-limiting example adaptive filtering method.

FIG. 5 is a schematic of a system for performing magnetic resonance imaging in accordance with the present disclosure.

FIG. 6A is a block diagram of an example of a k-space motion correction system.

FIG. 6B is a block diagram of components that can implement the k-space motion correction system of FIG. 6A.

### DETAILED DESCRIPTION

Systems and methods are provided for managing the acquisition of MRI k-space data to reduce artifacts caused by degraded data quality and scan times required to acquire all necessary data at the requisite data quality. MRI k-space data may be used to refer to and include any form of raw or non-reconstructed MR data acquired with an MRI system, including functional MRI (fMRI) data, resting state fMRI (rs-fMRI) data, perfusion-weighted data, and other MRI data, and the like. Real-time monitoring and prediction of degraded data quality may include, but is not limited to, patient motion during scanning. Methods, computer-readable storage devices, and systems are described for using a convolutional neural network (CNN) or other machine learning routines to assess data quality in k-space data collected from an MRI scanner during an MRI scan. In various aspects, a training or k-space reference dataset may be used with the k-space dataset to provide a common basis from which the data quality of all datasets may be obtained and compared.

In a non-limiting example, the MRI procedure may include acquiring functional magnetic resonance imaging (fMRI) data. The system and method in accordance with the present disclosure may be referred to as utilizing a “FIRMM” system or “FIRMM” technique to address motion-induced artifacts when acquiring MRI data with an MRI system. Such a FIRMM system or FIRMM technique facilitates real-time monitoring and prediction of motion of a body part of a patient, which may include, but is not limited to, motion during fMRI scanning, such as head motion.

The fMRI data used in accordance with the present disclosure may include task fMRI data, rs-fMRI data, or a combination thereof, and may also be referred to as Blood Oxygenation Level Dependent (BOLD) data or BOLD activity data. Task fMRI includes where a subject performs a take or responds to a stimuli while imaging is being performed. Resting-state fMRI is where the subject does not perform a task or respond to stimuli while imaging is being performed. Instead, the subject lies in the MR scanner for a period of time with eyes closed or staring at a fixed point while BOLD data is acquired. rs-fMRI demonstrates highly correlated low frequency (<0.1 Hz) changes in BOLD signals between different areas of the brain, which manifests the brain's functional connectivity. rs-fMRI presents unique challenges in that data must be acquired over long periods of time, and any motion by the subject may introduce detrimental errors or artifacts into the resulting images and thereby negate any diagnostic capability of the rs-fMRI scan.

In various aspects, the systems and methods described herein may improve MRI data quality and reduce costs associated with MRI data acquisition. In one aspect, a method in accordance with the present disclosure is implemented in the form of a software suite that calculates and displays data quality metrics and/or summary motion statistics in real time during an MRI data acquisition. In a non-limiting example, the display may be in the form of a GUI generated during MRI data acquisition.

The systems and methods provided herein overcome one or more of at least several shortcomings of previous systems. To address the shortcomings associated with overscanning by previous systems to compensate for motion-distorted data, the systems and methods provided herein may provide real-time feedback to the scanner operator and/or the subject undergoing the scan. The operator may receive feedback in the form of a display quantifying the amount of motion a subject has experienced during a scan. Sensory feedback may be provided to a subject during the scan based on the data quality metrics and summary motion statistics calculated in real-time, thereby enabling the subject to monitor and adjust their movements accordingly (e.g., remain still) in response to the provided feedback. The systems and methods may include providing stimulus conditions, such as viewing a fixation crosshair or a movie clip, to simultaneously engage the subject while also providing real-time feedback to the subject.

For the purposes of this disclosure and accompanying claims, the term “real time” or related terms are used to refer to and defined a real-time performance of a system, which is understood as performance that is subject to operational deadlines from a given event to a system's response to that event. For example, a real-time extraction of data and/or displaying of such data based on empirically-acquired signals may be one triggered and/or executed simultaneously with and without interruption of a signal-data acquisition (e.g., pulse sequence) or imaging procedure.

The shortcomings of conventional systems as described above may be addressed by enabling a scanner operator to continue each scan until the desired number of low- or no-movement datasets have been acquired, in accordance with the present disclosure. Non-limiting examples of reaching the desired number of low- or no-movement datasets include: predicting the number of usable datasets that will be available at the end of the scan; predicting the amount of time a given subject will likely have to be scanned until the preset time-to-criterion (minutes of low-movement FD data) has been acquired; enabling for the selection and deselection of specific individual scans for inclusion in the actual and predicted amount of low-movement data, and the like.

Previously, motion estimates for MRI studies were typically analyzed offline, either after data collection was completed for a given subject, or more commonly, in large batches after data collection for the whole cohort had been completed. Postponing motion analyses is expensive and risky, especially when scanning a previously unstudied patient population and after making changes to the data collection protocol or personnel.

Real-time information about data quality can be used to reduce degradations in data quality in multiple different ways including, but not limited to, influencing the behavior of MRI scanner operators, and influencing MRI scanning subject behavior. Scanner operators may be alerted about any sudden or unusual changes in head movement and may be enabled to interrupt such scans to investigate if the subject has started moving more because they have grown uncomfortable and whether a bathroom break, blanket, repositioning or other intervention could make them feel more comfortable. In some aspects, the methods provided herein further include options for feeding information about motion back to the subject, post-scan and/or in real time. The disclosed methods may allow scanner operators to find the “sweet spot” that provides the required amount of low- or no-movement data at the lowest cost. Following the methods, a scan could be stopped, the subject could be further instructed or reminded on ways to try remaining still, the scan could be re-acquired, and the like, to address motion.

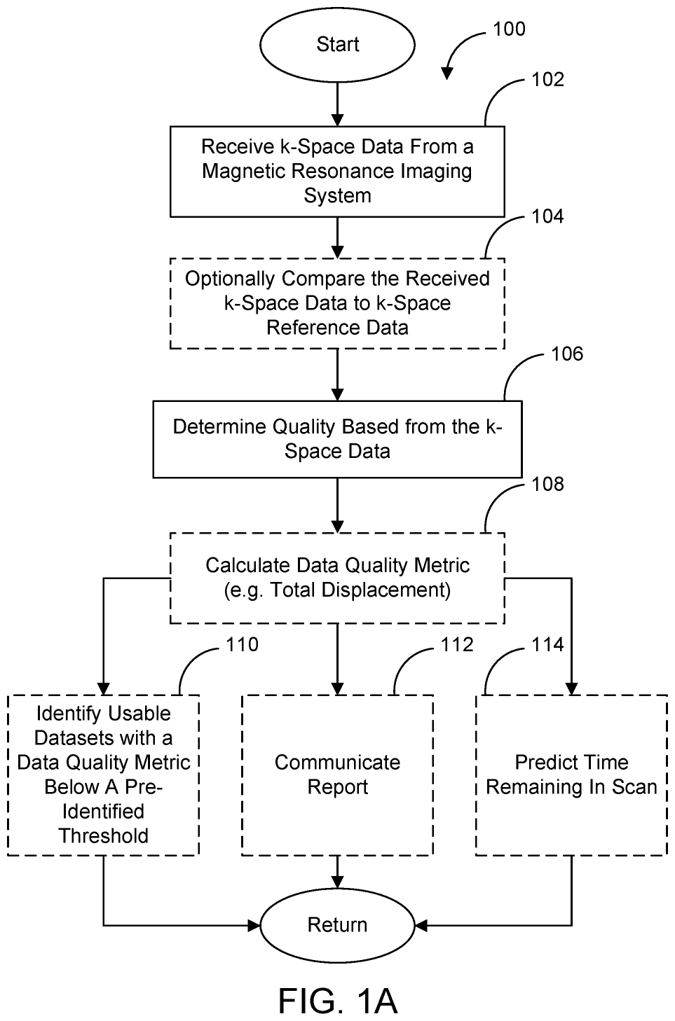

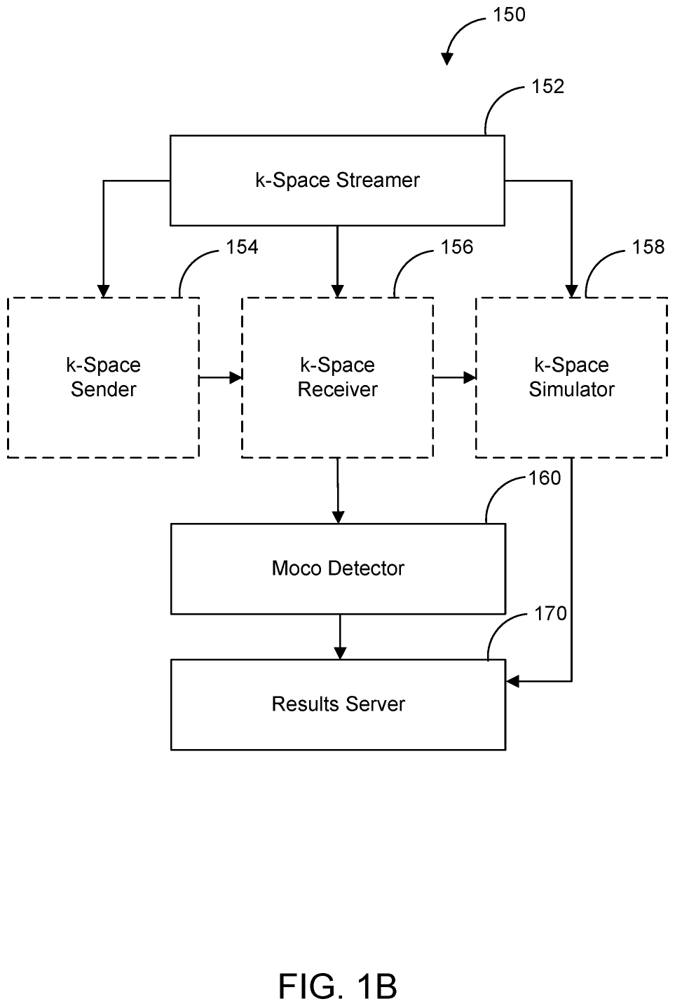

Referring to FIG. 1A, a non-limiting example method 100 for processing a set of k-space MRI datasets to assess the k-space data for indications of degraded data quality is shown. The method 100 includes receiving k-space MRI data at step 102 from a magnetic resonance imaging system in the form of raw MRI data. The k-space MRI data may be received by a computing device from a magnetic resonance imaging system via a network or from a storage medium coupled to or in communication with the computing device.

The method 100 may also include comparing the k-space dataset to a k-space reference dataset at step 104. However, this step 104 may be optional. A training or k-space reference dataset may be used with the k-space dataset to provide a common basis from which the data quality of all datasets may be obtained and compared. Alternatively, the k-space data received from the MRI system at step 102 may be directly assessed to determine data quality decreases without comparison at process block 104. For example, as will be described, the determination at process block 106 may employ a learning network or other artificial intelligence to analyze the k-space data for signs of degraded data quality.

If a comparison is performed at process block 104, each k-space dataset may be compared to the k-space reference dataset. A transform may be determined as Tᵢ, where i indexes the registration of dataset i to a k-space reference of dataset I, starting with the second dataset. Each transform may be calculated by minimizing the registration error to an absolute minimum or below a selected cutoff:

$${ε}_{i} = 〈 {( sIi ( T ( x ) ) - {I}_{1} ( \vec{x} ) )}^{2} 〉 \qquad ( 1 )$$

where I(x) is the intensity at locus x and s is a scalar factor that compensates for fluctuations in mean signal intensity, spatially averaged over the whole brain, as depicted by the angle brackets. In some aspects, the datasets may be realigned using a 4dfp cross_realign3d_4dfp algorithm (see Smyser, C. D. et al. 2010, Cerebral cortex 20, 2852-2862, (2010)), which is specifically incorporated herein by reference). Alternative alignment algorithms can also be utilized to align the datasets.

In various aspects, each transform may be represented by a combination of rotations and displacements as described by

$${T}_{i} = [ \begin{matrix}{R}_{i} & {d}_{i} \\ 0 & 1\end{matrix} ] \qquad ( 2 )$$

where Rᵢ represents the 3×3 matrix of rotations including the three elementary rotations at each of the three axes (see Example 1 below) and dᵢ represents the 3×1 column vector of displacements. Rᵢ may include the three elementary rotations at each of the three axes as expressed by: Rᵢ=R_{iα}R_{iβ}R_{iγ}, where α, β, and γ are rotation angles, and where

$${R}_{i α} = [ \begin{matrix}1 & 1 & 0 \\ 0 & cos ( {α}_{i} ) & - s in ( {α}_{i} ) \\ 0 & sin ( {α}_{i} ) & cos ( {α}_{i} )\end{matrix} ] \qquad ( 3 )$$

$${R}_{i {β}^{=}} [ \begin{matrix}cos ( {β}_{i} ) & 0 & sin {β}_{i} \\ 0 & 1 & 0 \\ - sin {β}_{i} & 0 & cos {β}_{i}\end{matrix} ] \qquad ( 4 )$$

$${R}_{i γ} = [ \begin{matrix}cos ( {γ}_{i} ) & - sin ( {γ}_{i} ) & 0 \\ sin ( {γ}_{i} ) & cos ( {γ}_{i} ) & 0 \\ 0 & 0 & 1\end{matrix} ] \qquad ( 5 )$$

The method 100 may, optionally, also include calculating the relative motion of, for example, data that may correspond to a body part between the dataset and the preceding dataset as indicated at step 108. For example, the method 100 quantify or estimate motion in the current k-space data relative to the preceding k-space data. The relative motion of a body part (e.g., head motion) may be calculated from the data. In one non-limiting example motion may be characterized relative to six alignment parameters, x, y, z, θₓ, θ_{y}, and θ_{ζ}, where x, y, z, are translations in the three coordinate axis and θₓ, θ_{y}, and θ_{ζ}, are rotations about those axis in the image domain (e.g., by further analyzing the k-space data in the image domain after potential motion is detected in the frequency domain).

The method 100 may also include calculating a data quality metric at step 108. In one non-limiting example the data quality metric may include or be based on a total displacement. In one non-limiting example, the displacement may be determined using multiple displacement vectors of motion. In a non-limiting example, total displacement may be calculated by adding the absolute displacement in six directions, thereby treating information in the data corresponding to movement of the body part as a rigid body. The motion of the I^{th} dataset, such as the I^{th} frame, may be converted to a scalar quantity using the formula:

Displacementi=|Adᵢₓ|+|Ad_{iy}|+|Ad_{iz}|+|Acq|+|Δβ;|+|Δγ:| (6)

where Δdᵢₓ=d_{(i_1)x}−dᵢₓ; Δd_{iy}=d_{(i_1)y}−d_{iy}; Δd_{iz}=d_{(i_1)z}−d_{iz}, and so forth, and Acq is the acquired k-space data.

If desired, any rotational displacements |Δ_{αi}|, |Δ_{βi}|, and |Δ_{γi}| may be converted to degrees or millimeters by computing displacement on the surface of a 3D volume representative of the body part being imaged in the image domain. In a non-limiting example, if the head is imaged, the 3D volume selected to calculate displacement in the image domain may be a sphere. Since each dataset is realigned to the reference dataset, displacement may be calculated by subtracting Displacement i−1 (for the previous dataset, which may correspond to a previous frame) from Displacement i (for the current dataset, which may correspond to a current frame).

In some aspects, the method 100 may further include excluding data with a cutoff above a pre-identified threshold of total displacement at step 110. Upon completion, the method 100 may return to the start for each subsequent dataset in the MRI scan. A display of the data quality metric may be performed at step 112, and a prediction of the time remaining in a scan may be performed at step 114.

Referring to FIG. 1B, a non-limiting example block diagram of a system 150 for processing a set of k-space MRI data to determine a subjects' movement, is shown. The system 150 includes a k-space streamer module 152, which may provide for transferring acquired k-space data from a scanner to a computer system or other workstation for further processing. Processing of k-space data may also be performed by a MRI system, with k-space streamer module 152 providing access to the k-space data. The k-space streamer module 152 may include a k-space sender sub-module 154, a k-space receiver sub-module 156, and a k-space simulator sub-module 158. The k-space sender sub-module 154 may be installed on the scanner, and my provide for opening a socket on the scanner for sending k-space data to a server as soon as possible, such as at the end of each repetition time (TR). The k-space receiver sub-module 156 may listen for connections from k-space sender sub-module 154, and upon receiving data, save the data to disk and/or notify any interested processes of the new data. The k-space simulator sub-module 158 may read data written by the receiver sub-module 156 and use it to simulate the sender sub-module 154. In some configurations, the simulator sub-module 158 may provide access to simulated data for subsequent development or refinement of the system 150.

k-space streamer module 152 may be used to collect a k-space reference data, as described above with FIG. 1A. A reference clinical protocol may be used when collecting k-space reference data with the MRI system. The size/scope of the k-space reference dataset may depend on how much other relevant data can be gathered during a preparatory phase. In a non-limiting example, a k-space reference dataset could be collected while using an optical region-of-interest (ROI) tracker, which may provide for very accurate ground-truth motion estimates for each TR. In another non-limiting example, the use of vNAVs may be used to generate a k-space reference data, however, there may not be vNAV-enabled sequences available for each entry in the reference clinical protocol.

System 150 may also include a “moco” detector 160 and a results server 170. The moco detector may be used to digest data from the k-space receiver sub-module 156, such as TR-by-TR, and produces an estimate of data quality or degradation, such as motion that occurred during the acquisition of the data. The motion estimate may then be sent to the results server 170 for dissemination. The results server 170 may be used to process or display the resulting motion estimates for any interested real-time applications.

Motion estimation by moco detector 160 may include determining an RMS displacement, and may be performed as indicated in FIG. 1A. In a non-limiting example, results server 170 may be configured to display an estimation of motion that includes RMS displacement per minute (RMSpm). Moco detector 160 may use a machine learning/deep learning system to estimate motion, such as using a convolutional neural network (CNN) that has been trained via supervised learning. Any appropriately trained deep learning framework may be used, such as TensorFlow, PyTorch, Keras, Sonnet, MXNet, Swift for TensorFlow, Gluon, DL4J, ONNX, Chainer, and the like (upgrad.com/blog/top-deep-learning-frameworks/). A trained CNN may be able to quickly estimate motion that occurred during an MRI procedure.

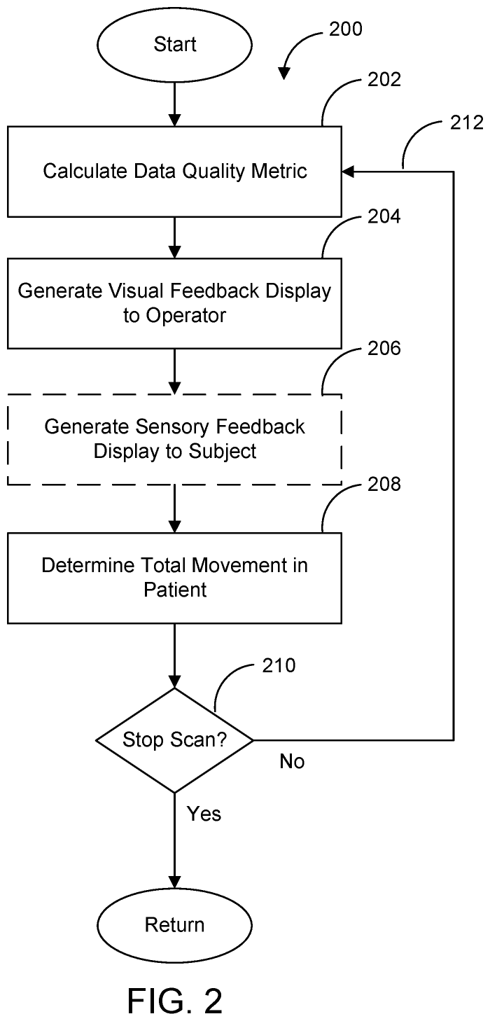

Referring to FIG. 2, a flow chart illustrating a non-limiting example method 200 for providing a sensory feedback to the operator of the MRI system and/or the patient within the MRI system during data acquisition is shown. The method 200 may include calculating a data quality metric at step 202 based on one or more components of movement determined for the patient in the MRI device during scanning. The data quality metric calculated at step 202 may include, but not be limited to, any one or more of the displacement components as described above, an overall displacement as described above, other data quality metrics including DVARS as described above, and any combination thereof.

The method 200 includes generating a visual display in real-time to an operator of the MRI system at step 204 based on at least a portion of the data quality metric calculated at step 202. Non-limiting examples of suitable visual feedback displays include at least a portion of a GUI, a light bar, a video, an image, and the like. In various aspects, the visual feedback display for the operator of the MRI system may include visual elements including, but not limited to, one or more graphs displaying the data quality metrics for all data received in the scan, tables of summary statistics regarding the quality of the current and previous scans, graphical or tabular elements communicating the cumulative number of useable data obtained in the current scan, tabular or graphical elements communicating the amount of time remaining in the current scan and/or the predicted amount of time remaining in the current scan to obtain a predetermined number of useable scans, as described herein, and any combination thereof. In various aspects, the elements of the visual feedback display may be updated at any preselected rate up to a real-time rate of updating each display as each relevant quantity is calculated. The elements of the visual feedback display may be updated in response to a request from the operator of the MRI system, and the elements of the visual feedback display may dynamically updated in response to at least one of a plurality of factors including, but not limited to, significant increases in the monitored motion of the subject between data, cumulative motion, or any other suitable criteria.

The method 200 may optionally include generating a sensory feedback display at step 206 for the patient in the scanner during acquisition of MRI data. As described in additional detail below, the sensory feedback display generated at step 206 may be updated at a wide variety of refresh rates ranging from a single update at the end of scanning to continuously updating in real time, based on at least one of a plurality of factors including, but not limited to the patient's age and condition.

In various aspects, the method 200 may further include determining the total movement of the patient at step 208 between the previous data and the current data in response to the sensory feedback display generated at step 206. In one aspect, the method 200 further includes evaluating at least one of a plurality of factors to determine whether the current MRI scan should be terminated at step 210. In various aspects, the scan may be terminated in accordance with at least one of a plurality of termination criteria including, but not limited to, one of more movements of an unacceptably high magnitude, and unacceptably high number of relatively low magnitude movements, a determination that a suitable number of useable data were obtained, a prediction that a suitable number of useable data cannot be obtained in the time remaining in the scan, a prediction that a suitable number of useable data cannot be obtained within a reasonable cumulative scan time, and any combination thereof. If it is determined at step 210 to continue the scan, the method 200 may communicate at least one feedback signal 212 to be used in part to calculate the data quality metric at step 202 to start another iteration of the method 200 for subsequent data.

In one aspect, the systems and methods provided herein may provide a visual feedback display to the subject undergoing the MRI scan. In this aspect, a characteristic of the visual feedback display may change to communicate the occurrence of movement of the subject based on the detected data quality obtained using the method as described above. Any characteristic of one or more elements of a visual feedback display may be selected to vary in order to communicate the occurrence of movement including, but not limited to, a size, a shape, a color, a texture, a brightness, a focus, a position, a blinking rate, any other suitable characteristic of a visual element, and any combination thereof.

In another aspect, an auditory feedback display may be provided to the subject undergoing the MRI scan. A characteristic of the auditory feedback display may change to communicate the occurrence of movement of the subject based on the detected motion of the subject obtained using the method as described above. Any characteristic of one or more elements of an auditory visual feedback display may be selected to vary in order to communicate the occurrence of movement including, but not limited to, a pause in the playback of a musical selection, a resumption of playback of a musical selection, a verbal cue, a volume of a tone, a pitch of a tone, a duration of each tone in a series, a repeat rate of a series of tones, a steadiness or waver in a pitch or volume of a tone, any other suitable characteristic of an auditory feedback, and any combination thereof.

In various aspects, a characteristic of a sensory feedback display may vary based on a degree or magnitude of detected movement by the subject in the MRI scanner. In one aspect, the characteristic of the sensory feedback display may vary continuously in proportion to the degree of detected movement of the subject. In another aspect, the characteristic of the sensory feedback display may change within a discrete set of characteristics, in which each characteristic in the discrete set is configured to communicate the occurrence of one level of movement including, but not limited to, no movement, low movement, a medium or intermediate level of movement, and a high degree of movement.

In various other aspects, the sensory feedback display may vary in response to changes in a single component of movement, such as a translation in a single x, y, or z direction or a rotation about a single x, y, or z direction. The sensory feedback display may vary in response to changes in a combination of two or more components of movement, or the sensory feedback display may vary in response to an overall movement metric such as displacement described above. In one aspect, a single characteristic of the sensory feedback display is varied to communicate the occurrence of movement to the subject. In another aspect, two or more characteristics of the sensory feedback are varied independently to communicate the occurrence of movement to the subject, in which each characteristic varies based on a subset of the components of movement. By way of non-limiting example, a sensory feedback display may include a first characteristic that varies based on movement of the subject in the x-direction, and a second characteristic that varies independently based on combined movement of the subject in the y-direction and z-direction. In a non-limiting example, the sensory feedback display may include color coded indications being displayed to the patient, such as using red to indicate motion has occurred in the x-direction, and green for motion in the y-direction, and blue for motion in the z-direction.

In various aspects, the frequency at which the characteristics of a sensory feedback display are updated may range from a single feedback display at the end of a scan to communicate whether or not sufficiently low movement was maintained during the scan to a frequency commensurate with the real-time frequency at which movement is monitored by the method, and at any intermediate frequency without limitation. In various aspects, the frequency at which the characteristics of a sensory feedback display are updated may be selected based on at least one characteristic of the subject to be imaged in the MRI scanner including but not limited to, age of the subject, a condition of the subject such as attention deficit disorder or a learning disability, and any other relevant characteristic of the subject without limitation. In various aspects, the method provides for feedback based on a motion value from a single dataset or a combination of motion values across multiple datasets. In various other aspects, the method provides for real-time feedback and time delayed feedback. By way of on-limiting example, if a high update frequency is used for a sensory feedback display for a very young child, the display may encourage the child to increase movement within the MRI scanner as a way of providing a more entertaining and dynamic sensory feedback experience. In various aspects, the frequency at which the characteristics of a sensory feedback display are updated may be specified to be a constant update rate throughout MRI scanning, or the update rate may dynamically vary based on an instantaneous and/or cumulative assessment of the motion of the subject.

In a non-limiting example of sensory feedback, a subject undergoing the MRI scan may be instructed to view a fixation crosshair (e.g., a target). The crosshair may be color-coded based on the subject's detected movement (e.g., head motion), and the subject may be instructed to maintain the crosshair at a certain color (e.g., a first color) by remaining still during the scan. As a consequence of detected changes in the subject's movement, the crosshair may change to a second color (e.g., to represent medium movement) or a third color (e.g., to represent high movement), thereby enabling the subject to monitor and adjust his or her own movement during the scan.

In a non-limiting example of sensory feedback, a subject undergoing an MRI scan may be instructed to watch a movie clip. Based on the subject's level of movement (e.g. low movement, medium movement, high movement), a visual impediment on the movie clip may prevent the subject from viewing parts of the movie clip. For example, the subject may be instructed to remain still during the scan in order to watch an unobstructed view of the movie clip. Based on the subject's level of movement, the movie clip may be obstructed by a rectangular block of a certain size (e.g., a small yellow-colored rectangle for medium movement, and a large red-colored rectangular for high movement). Thus, the subject may be able to monitor and adjust his or her own movement during the scan based on the real-time visual feedback.

Fixed and adaptive feedback conditions may be provided for the real-time visual displays or sensory feedback. In one aspect for fixed feedback conditions, thresholds for low, medium, and high motions may be held constant for the duration of the MRI scan. In another aspect for adaptive feedback conditions, thresholds for low, medium, and high motions may change and be replaced with stricter (e.g. lower) threshold values during the duration of the MRI scan. With adaptive feedback conditions, the MRI scanner may adapt to the subject's ability to remain still, and, for example, increase the difficulty level of keeping the crosshair a first color or the movie clip visibly unobstructed.

In some aspects, changes in MRI acquisition procedures including, but not limited to, multiband imaging, enable improved temporal and spatial resolution relative to previous MRI acquisition procedures. However, the improved temporal and spatial resolution may be accompanied by artifacts in motion estimates from post-acquisition data alignment procedures, thought to be caused primarily by chest motion during respiration. Without being limited to any particular theory, chest motion associated with respiration changes the static magnetic field (Bo) during MRI data acquisition, and such ‘tricks’ any dataset-to-dataset alignment procedure used in real-time motion monitoring into correcting a ‘head movement’ even in the absence of actual head movement. In one aspect, an optional band-stop (or notch) filter to remove respiration-related artifacts from motion estimates is provided, thereby enhancing the accuracy of real-time representations of motion.

A notch filter (e.g., band-stop filter) may be applied to motion measurements to remove artifacts from motion estimates caused by a subject's breathing. A subject's breathing may contaminate movement estimates in MRI, and thereby distorts the quality of MRI data obtained. Some aspects utilize a general notch filter to capture a large portion of a sample population's respiration peak with respect to power. A subject-specific filter based on filter parameters specific to a subject's respiratory belt data may be used.

The band-stop (e.g., notch filter) may be implemented to remove the spurious signal in the motion estimates that correspond to the aliased respiration rate. This filter may remove the undesired frequency components while leaving the other components unaffected. The notch filter may include design parameters of the central cutoff frequency and the bandwidth or range of frequencies that will be eliminated. To establish the parameters for the central cutoff frequency and the bandwidth, a distribution of respiration rates obtained from various subjects of MRI during data acquisition may be analyzed, and a median of the distribution may be used as the cutoff frequency, and the quartiles 2 and 3 of the distribution may be used to determine bandwidths of the notch filter. Subsequent to establishing these parameters, an MR notch filter function may be used to design the notch filter. For a given sampling rate (1/TR), the respiratory rates may not be aliased. In other cases, when the combination of TR and respiration rate leads to aliasing, the aliased respiration rate may be used instead.

The designed filter may include a difference equation. When applied to a sequence representing a motion estimate, this difference equation may recursively weight the two previous samples to provide an instantaneous filtered signal. This procedure may start with the third sample, weight the two previous points, and continue until the last time-point is filtered. The filtered signal in such an implementation may have a phase delay with respect to the original signal. This phase delay may be compensated for by applying the filter twice, once forward and the second time backwards such that the opposite phase lags cancel out each other. Once the filter is applied to the entire sequence, the same filter (difference equation) may be reapplied backwards, with the last time-point of the forward-filtered sequence used as the first point for the backward application of the filter, and the recursive process may be continued until the first time-point of the forward-filtered sequence is filtered. In various aspects, the designed notch filters (general and subject-specific) may be applied to a sequence of motion estimates post-processing to improve data quality.

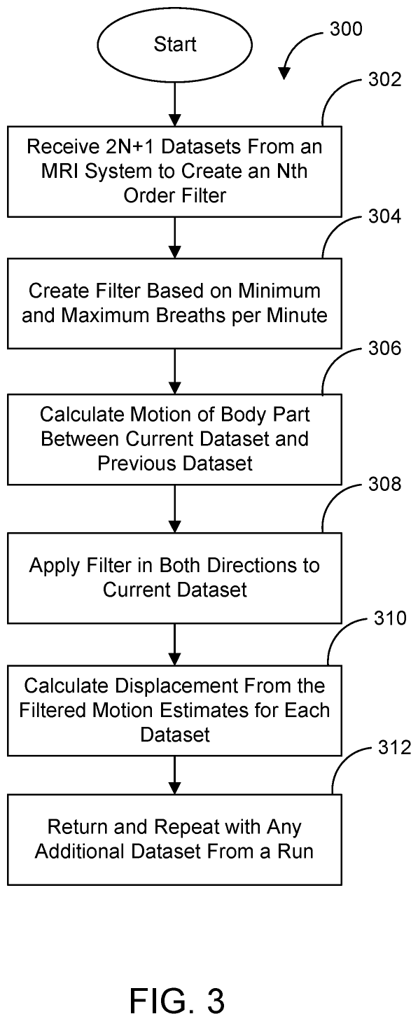

Referring to FIG. 3, a flow chart illustrating a non-limiting example method 300 for removing artifacts associated with detected motion data, such as respiration, using an Nth order filter is shown. In one aspect, the method 300 includes receiving 2N+1 datasets from the MRI system at step 302 that are used to create the Nth order filter. In addition to the 2N+1 datasets, the method 300 may further include creating the Nth order filter based on minimum and maximum respiratory frequencies at step 304. In various aspects, the subject's respiratory rate may be obtained using a variety of devices and methods including but not limited to, a respiratory monitor belt fitted to the subject, extracting respiratory frequency information from MRI signals obtained from the patient in the MRI scanner, and any other suitable method without limitation.

The method 300 may further include calculating a motion of a body part of the patient using the methods described herein at step 306. The method may further include applying the Nth order filter created at step 302 to the current dataset set in a forward and reverse direction with respect to data acquisition time at step 308. The Nth order filter in both directions may be used to eliminate a phase lag from the filtered data. Using the filtered motion estimates, a data quality metric including, but not limited to displacement may be calculated at step 310. If additional datasets are obtained at step 312, the method may replace the earliest dataset in the 2N+1 datasets received previously at step 302 with the dataset received at step 312 to initiate a subsequent iteration of the method 300.

The designed filter may also be applied in real time, since each instantaneous estimate of motion can be filtered out by weighting previous estimates following the notch filter's difference equation. In one aspect, the filter is run in pseudo-real time to minimize any resulting phase lag. In this aspect, once a specified number of samples are obtained, such as 5 samples in a non-limiting example, the filter could be applied twice and the best estimate would be the value corresponding to the third sample. This delayed signal will not have a phase delay. As each new sample is obtained, the filter can be applied twice to the entire sequence and the process can be repeated. Each time a new sample is measured, the filtered sequence will converge closer to the optimal output obtained when the filter is applied twice to the entire sequence. At the final dataset of a given run, the filtered sequence is then identical to the filtered sequence obtained during post-processing. Thus, the designed notch filters may be used in real-time to improve the accuracy of real-time estimates of motion using the motion prediction method described above.

In various aspects, adaptive filtering methods, including least squares adaptive filtering, may be applied in real-time to identify and remove signal content associated with undesired frequencies from subject movement data, such as cardiac and/or respiratory frequencies, from measured subject movement data including, but not limited to, displacement data, without concurrently introducing a phase lag to these data. In one aspect, a real-time adaptive filter may be used to remove respiratory-related artifacts from the MRI data.

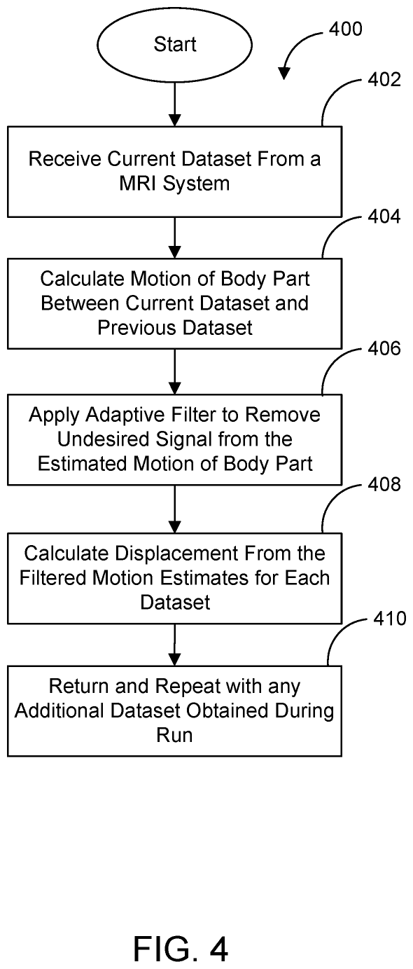

Referring to FIG. 4, a flowchart illustrating a non-limiting example adaptive filtering method 400 is shown. The method makes use of an unfiltered signal at step 402 including, but not limited to, displacement (such as, for example, framewise displacement (FD)) data derived from datasets obtained from the subject in the MRI scanner using the method described above, as well as a best estimate of the noise signal at step 404 to be eliminated using the adaptive filter at step 406. The adaptive filter method 400 may minimize in real time by gradient descent the contribution of the undesired signal into the measured signal, providing an optimal filtered sequence at step 408. The method may be repeated at step 410. Non-limiting examples of suitable noise signals to be input to the adaptive filter include real-time measurements of the respiration rate of the subject in the MRI scanner, the sum of multiple sinusoidal signals at different phases with frequencies corresponding to the respiration rate of the subject, and any other suitable estimate of the subject's respiration rate. In one aspect, the respiration rate of the participant could be measured while the Tiw or a previous sequence is acquired and used as the signal noise input.

In one aspect, the adaptive filter method 400 includes receiving a first estimation of head movement in each direction (i.e., x, y, z, θₓ, θ_{y}, θ_{ζ}) as determined using the method described above. This first estimation of head movement includes both the real head movement(s) and the undesired artifact (n₀). These two signals(s) and (n₀) may be assumed to be independent and uncorrelated. An additional input may be used of a best estimation of the undesired artifact (n₁=n₀) received. If the undesired artifact no corresponds to respiration rate, this signal may be provided as a real time measurement of the respiration rate. In another aspect, if real time measurements of respiration are not available, a sinusoidal signal comprising a sum of a plurality of sinusoidal signals may be generated, in which the most likely respiration rate corresponds to the subject in the scanner. This error signal may be filtered out by the adaptive filter to generate an optimized estimate of the error signal (y(T)). In this aspect, the goal of the adaptive filter may be to maximize the correlation of the optimized estimate of the error signal (y(T)) and the measured estimation of head movement (d(T)). When the first dataset is used, the adaptive filter may have no effect on the signal (n₀). Also in this aspect, the optimized estimate of the error signal (y(T)) may be subtracted from the measured estimation of head movement (d(T)) to calculate the error signal (i.e. e(T)=s+n₀−y(T)). This error may be used as a feedback signal to modify the parameters of the adaptive filter to make the signal (y(t)) as correlated as possible to the measurement (d(T)). As the real head movement(s) and the real artifact (no) are uncorrelated, maximizing the correlation between no and d(T) may be driven by the match between no and no. Hence, subtracting those signals (d(T) and y(T)) removes the undesired artifact. In one aspect, an adaptive filter method may be implemented using well-established methods in which the parameters of a second order difference equation are optimized to maximize the estimation of the undesired artifact.

In various aspects, the methods in accordance with the present disclosure may be implemented by a system that includes an MRI system and one or more processors or computing devices. In various aspects, one or more operations described herein may be implemented by one or more processors having physical circuitry programmed to perform the operations. In various other aspects, one or more steps of the method may automatically be performed by one or more processors or computing devices. In various additional aspects, the various acts illustrated may be performed in the illustrated sequence, in other sequences, in parallel, or in some cases, may be omitted.

In some aspects, the above described methods and processes may be implemented using a computing system, including one or more computers. The methods and processes described herein may be implemented as a computer application, computer service, computer API, computer library, and/or other computer program product.

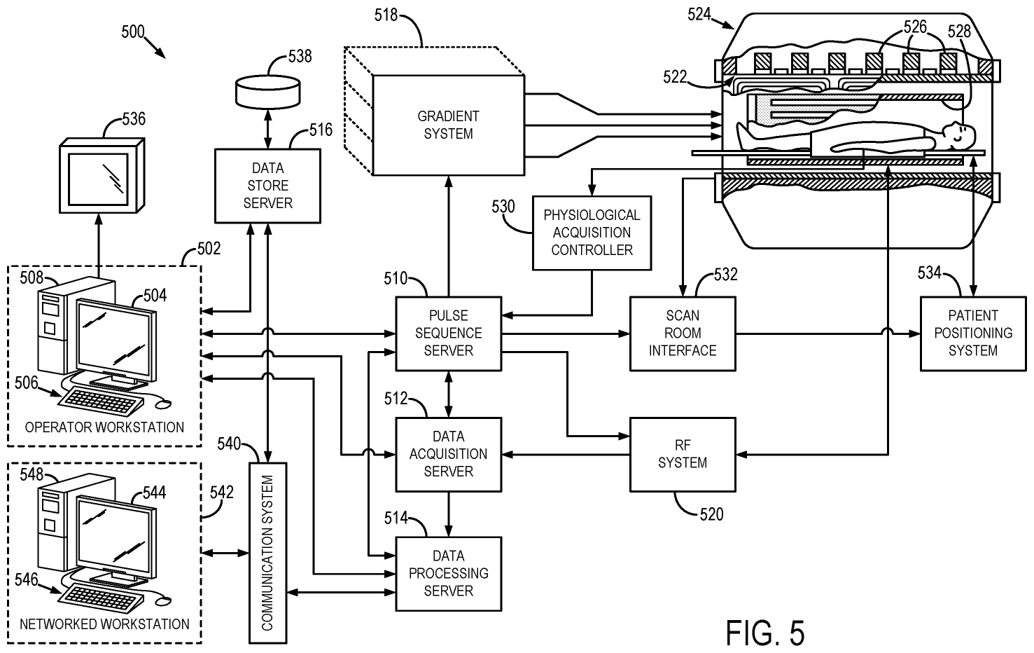

Referring to FIG. 5, an example of an MRI system 500 that can implement the methods described here is illustrated. The MRI system 500 includes an operator workstation 502 that may include a display 504, one or more input devices 506 (e.g., a keyboard, a mouse), and a processor 508. The processor 508 may include a commercially available programmable machine running a commercially available operating system. The operator workstation 502 provides an operator interface that facilitates entering scan parameters into the MRI system 500. The operator workstation 502 may be coupled to different servers, including, for example, a pulse sequence server 510, a data acquisition server 512, a data processing server 514, and a data store server 516. The operator workstation 502 and the servers 510, 512, 514, and 516 may be connected via a communication system 540, which may include wired or wireless network connections.

The pulse sequence server 510 functions in response to instructions provided by the operator workstation 502 to operate a gradient system 518 and a radiofrequency (“RF”) system 520. Gradient waveforms for performing a prescribed scan are produced and applied to the gradient system 518, which then excites gradient coils in an assembly 522 to produce the magnetic field gradients Gₓ, G_{y}, and G_{z} that are used for spatially encoding magnetic resonance signals. The gradient coil assembly 522 forms part of a magnet assembly 524 that includes a polarizing magnet 526 and a whole-body RF coil 528.

RF waveforms are applied by the RF system 520 to the RF coil 528, or a separate local coil to perform the prescribed magnetic resonance pulse sequence. Responsive magnetic resonance signals detected by the RF coil 528, or a separate local coil, are received by the RF system 520. The responsive magnetic resonance signals may be amplified, demodulated, filtered, and digitized under direction of commands produced by the pulse sequence server 510. The RF system 520 includes an RF transmitter for producing a wide variety of RF pulses used in MRI pulse sequences. The RF transmitter is responsive to the prescribed scan and direction from the pulse sequence server 510 to produce RF pulses of the desired frequency, phase, and pulse amplitude waveform. The generated RF pulses may be applied to the whole-body RF coil 528 or to one or more local coils or coil arrays.

The RF system 520 also includes one or more RF receiver channels. An RF receiver channel includes an RF preamplifier that amplifies the magnetic resonance signal received by the coil 528 to which it is connected, and a detector that detects and digitizes the I and Q quadrature components of the received magnetic resonance signal. The magnitude of the received magnetic resonance signal may, therefore, be determined at a sampled point by the square root of the sum of the squares of the I and Q components:

$$M = \sqrt{{I}^{2} + {Q}^{2}} ; \qquad ( 7 )$$

and the phase of the received magnetic resonance signal may also be determined according to the following relationship:

$$φ = {tan}^{- 1} ( \frac{Q}{I} ) . \qquad ( 8 )$$

The pulse sequence server 510 may receive patient data from a physiological acquisition controller 530. By way of example, the physiological acquisition controller 530 may receive signals from a number of different sensors connected to the patient, including electrocardiograph (“ECG”) signals from electrodes, or respiratory signals from a respiratory bellows or other respiratory monitoring devices. These signals may be used by the pulse sequence server 510 to synchronize, or “gate,” the performance of the scan with the subject's heart beat or respiration.

The pulse sequence server 510 may also connect to a scan room interface circuit 532 that receives signals from various sensors associated with the condition of the patient and the magnet system. Through the scan room interface circuit 532, a patient positioning system 534 can receive commands to move the patient to desired positions during the scan.

The digitized magnetic resonance signal samples produced by the RF system 520 are received by the data acquisition server 512. The data acquisition server 512 operates in response to instructions downloaded from the operator workstation 502 to receive the real-time magnetic resonance data and provide buffer storage, so that data is not lost by data overrun. In some scans, the data acquisition server 512 passes the acquired magnetic resonance data to the data processor server 514. In scans that require information derived from acquired magnetic resonance data to control the further performance of the scan, the data acquisition server 512 may be programmed to produce such information and convey it to the pulse sequence server 510. For example, during pre-scans, magnetic resonance data may be acquired and used to calibrate the pulse sequence performed by the pulse sequence server 510. As another example, navigator signals may be acquired and used to adjust the operating parameters of the RF system 520 or the gradient system 518, or to control the view order in which k-space is sampled. In still another example, the data acquisition server 512 may also process magnetic resonance signals used to detect the arrival of a contrast agent in a magnetic resonance angiography (“MRA”) scan. For example, the data acquisition server 512 may acquire magnetic resonance data and processes it in real-time to produce information that is used to control the scan.

The data processing server 514 receives magnetic resonance data from the data acquisition server 512 and processes the magnetic resonance data in accordance with instructions provided by the operator workstation 502. Such processing may include, for example, reconstructing two-dimensional or three-dimensional images by performing a Fourier transformation of raw k-space data, performing other image reconstruction algorithms (e.g., iterative or backprojection reconstruction algorithms), applying filters to raw k-space data or to reconstructed images, generating functional magnetic resonance images, or calculating motion or flow images.

Images reconstructed by the data processing server 514 are conveyed back to the operator workstation 502 for storage. Real-time images may be stored in a data base memory cache, from which they may be output to operator display 502 or a display 536. Batch mode images or selected real time images may be stored in a host database on disc storage 538. When such images have been reconstructed and transferred to storage, the data processing server 514 may notify the data store server 516 on the operator workstation 502. The operator workstation 502 may be used by an operator to archive the images, produce films, or send the images via a network to other facilities.

The MRI system 500 may also include one or more networked workstations 542. For example, a networked workstation 542 may include a display 544, one or more input devices 546 (e.g., a keyboard, a mouse), and a processor 548. The networked workstation 542 may be located within the same facility as the operator workstation 502, or in a different facility, such as a different healthcare institution or clinic.

The networked workstation 542 may gain remote access to the data processing server 514 or data store server 516 via the communication system 540. Accordingly, multiple networked workstations 542 may have access to the data processing server 514 and the data store server 516. In this manner, magnetic resonance data, reconstructed images, or other data may be exchanged between the data processing server 514 or the data store server 516 and the networked workstations 542, such that the data or images may be remotely processed by a networked workstation 542.

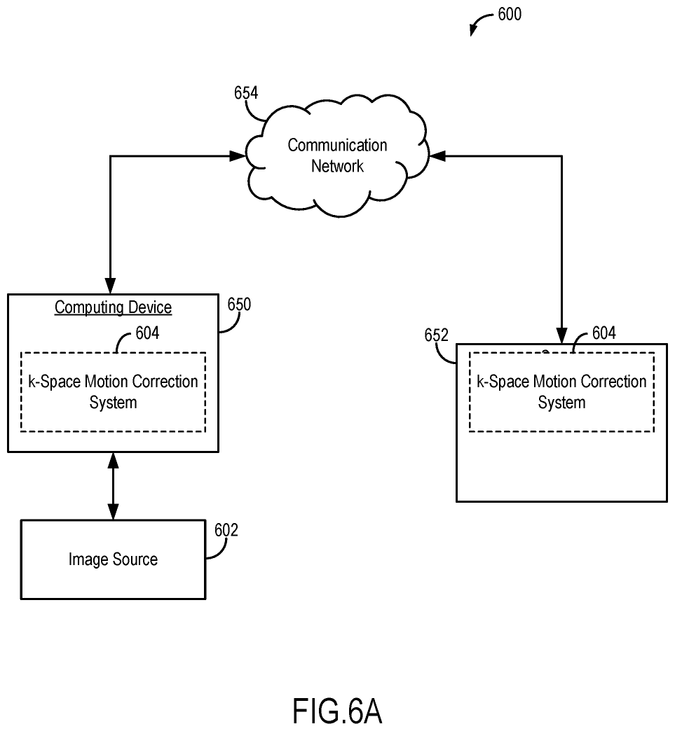

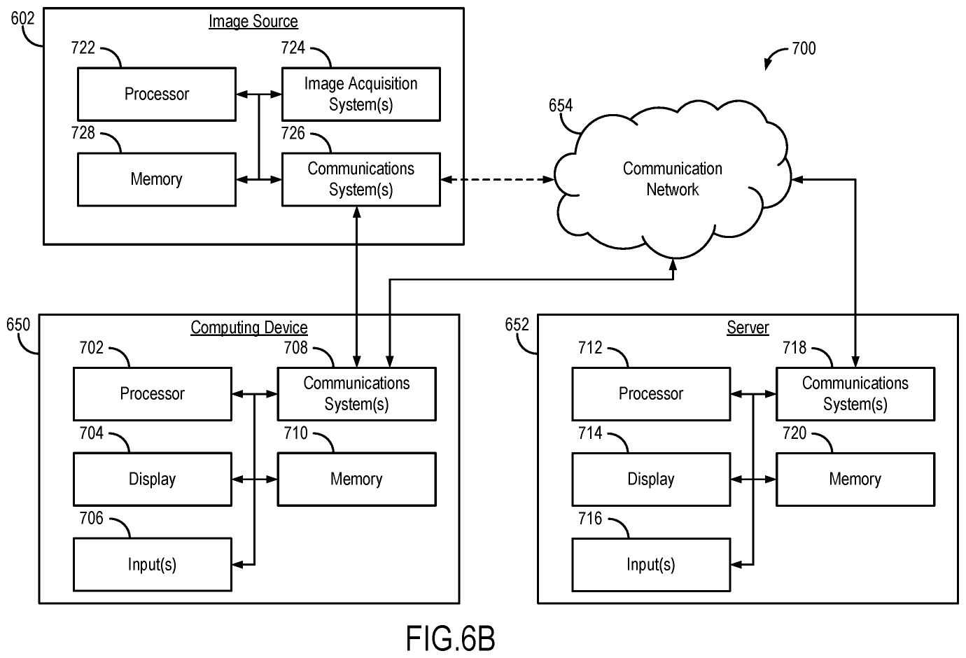

Referring now to FIG. 6A, an example of a system 600 for k-space motion correction (e.g., determination of motion between a k-space reference dataset and a k-space dataset) in accordance with some embodiments of the systems and methods described in the present disclosure is shown. As shown in FIG. 6A, a computing device 650 can receive one or more types of data (e.g., k-space MRI data) from image source 602, which may be an MRI source. In some embodiments, computing device 650 can execute at least a portion of a k-space motion correction system 604 to correct for motion in data received from the image source 602.

Additionally or alternatively, in some embodiments, the computing device 650 can communicate information about data received from the image source 602 to a server 652 over a communication network 654, which can execute at least a portion of the functional mapping-guided intervention targeting system 604. In such embodiments, the server 652 can return information to the computing device 650 (and/or any other suitable computing device) indicative of an output of the k-space motion correction system 604.

In some embodiments, computing device 650 and/or server 652 can be any suitable computing device or combination of devices, such as a desktop computer, a laptop computer, a smartphone, a tablet computer, a wearable computer, a server computer, a virtual machine being executed by a physical computing device, and so on. The computing device 650 and/or server 652 can also reconstruct images from the data.

In some embodiments, image source 602 can be any suitable source of image data (e.g., measurement data, images reconstructed from measurement data), such as an magnetic resonance imaging system, another computing device (e.g., a server storing image data), and so on. In some embodiments, image source 602 can be local to computing device 650. For example, image source 602 can be incorporated with computing device 650 (e.g., computing device 650 can be configured as part of a device for capturing, scanning, and/or storing images). As another example, image source 602 can be connected to computing device 650 by a cable, a direct wireless link, and so on. Additionally or alternatively, in some embodiments, image source 602 can be located locally and/or remotely from computing device 650, and can communicate data to computing device 650 (and/or server 652) via a communication network (e.g., communication network 654).

In some embodiments, communication network 654 can be any suitable communication network or combination of communication networks. For example, communication network 654 can include a Wi-Fi network (which can include one or more wireless routers, one or more switches, etc.), a peer-to-peer network (e.g., a Bluetooth network), a cellular network (e.g., a 3G network, a 4G network, etc., complying with any suitable standard, such as CDMA, GSM, LTE, LTE Advanced, WiMAX, etc.), a wired network, and so on. In some embodiments, communication network 654 can be a local area network, a wide area network, a public network (e.g., the Internet), a private or semi-private network (e.g., a corporate or university intranet), any other suitable type of network, or any suitable combination of networks. Communications links can each be any suitable communications link or combination of communications links, such as wired links, fiber optic links, Wi-Fi links, Bluetooth links, cellular links, and so on.

Referring now to FIG. 6B, an example of hardware 700 that can be used to implement image source 602, computing device 650, and server 652 in accordance with some embodiments of the systems and methods described in the present disclosure is shown. As shown in FIG. 6B, in some embodiments, computing device 650 can include a processor 702, a display 704, one or more inputs 706, one or more communication systems 708, and/or memory 710. In some embodiments, processor 702 can be any suitable hardware processor or combination of processors, such as a central processing unit (“CPU”), a graphics processing unit (“GPU”), and so on. In some embodiments, display 704 can include any suitable display devices, such as a computer monitor, a touchscreen, a television, and so on. In some embodiments, inputs 706 can include any suitable input devices and/or sensors that can be used to receive user input, such as a keyboard, a mouse, a touchscreen, a microphone, and so on.

In some embodiments, communications systems 708 can include any suitable hardware, firmware, and/or software for communicating information over communication network 654 and/or any other suitable communication networks. For example, communications systems 708 can include one or more transceivers, one or more communication chips and/or chip sets, and so on. In a more particular example, communications systems 708 can include hardware, firmware and/or software that can be used to establish a Wi-Fi connection, a Bluetooth connection, a cellular connection, an Ethernet connection, and so on.

In some embodiments, memory 710 can include any suitable storage device or devices that can be used to store instructions, values, data, or the like, that can be used, for example, by processor 702 to present content using display 704, to communicate with server 652 via communications system(s) 708, and so on. Memory 710 can include any suitable volatile memory, non-volatile memory, storage, or any suitable combination thereof. For example, memory 710 can include RAM, ROM, EEPROM, one or more flash drives, one or more hard disks, one or more solid state drives, one or more optical drives, and so on. In some embodiments, memory 710 can have encoded thereon, or otherwise stored therein, a computer program for controlling operation of computing device 650. In such embodiments, processor 702 can execute at least a portion of the computer program to present content (e.g., images, user interfaces, graphics, tables), receive content from server 652, transmit information to server 652, and so on.

In some embodiments, server 652 can include a processor 712, a display 714, one or more inputs 716, one or more communications systems 718, and/or memory 720. In some embodiments, processor 712 can be any suitable hardware processor or combination of processors, such as a CPU, a GPU, and so on. In some embodiments, display 714 can include any suitable display devices, such as a computer monitor, a touchscreen, a television, and so on. In some embodiments, inputs 716 can include any suitable input devices and/or sensors that can be used to receive user input, such as a keyboard, a mouse, a touchscreen, a microphone, and so on.

In some embodiments, communications systems 718 can include any suitable hardware, firmware, and/or software for communicating information over communication network 654 and/or any other suitable communication networks. For example, communications systems 718 can include one or more transceivers, one or more communication chips and/or chip sets, and so on. In a more particular example, communications systems 718 can include hardware, firmware and/or software that can be used to establish a Wi-Fi connection, a Bluetooth connection, a cellular connection, an Ethernet connection, and so on.

In some embodiments, memory 720 can include any suitable storage device or devices that can be used to store instructions, values, data, or the like, that can be used, for example, by processor 712 to present content using display 714, to communicate with one or more computing devices 650, and so on. Memory 720 can include any suitable volatile memory, non-volatile memory, storage, or any suitable combination thereof. For example, memory 720 can include RAM, ROM, EEPROM, one or more flash drives, one or more hard disks, one or more solid state drives, one or more optical drives, and so on. In some embodiments, memory 720 can have encoded thereon a server program for controlling operation of server 652. In such embodiments, processor 712 can execute at least a portion of the server program to transmit information and/or content (e.g., data, images, a user interface) to one or more computing devices 650, receive information and/or content from one or more computing devices 650, receive instructions from one or more devices (e.g., a personal computer, a laptop computer, a tablet computer, a smartphone), and so on.

In some embodiments, image source 602 can include a processor 722, one or more image acquisition systems 724, one or more communications systems 726, and/or memory 728. In some embodiments, processor 722 can be any suitable hardware processor or combination of processors, such as a CPU, a GPU, and so on. In some embodiments, the one or more image acquisition systems 724 are generally configured to acquire data, images, or both, and can include an MRI imaging system. Additionally or alternatively, in some embodiments, one or more image acquisition systems 724 can include any suitable hardware, firmware, and/or software for coupling to and/or controlling operations of an MRI system. In some embodiments, one or more portions of the one or more image acquisition systems 724 can be removable and/or replaceable.

Note that, although not shown, image source 602 can include any suitable inputs and/or outputs. For example, image source 602 can include input devices and/or sensors that can be used to receive user input, such as a keyboard, a mouse, a touchscreen, a microphone, a trackpad, a trackball, and so on. As another example, image source 602 can include any suitable display devices, such as a computer monitor, a touchscreen, a television, etc., one or more speakers, and so on.

In some embodiments, communications systems 726 can include any suitable hardware, firmware, and/or software for communicating information to computing device 650 (and, in some embodiments, over communication network 654 and/or any other suitable communication networks). For example, communications systems 726 can include one or more transceivers, one or more communication chips and/or chip sets, and so on. In a more particular example, communications systems 726 can include hardware, firmware and/or software that can be used to establish a wired connection using any suitable port and/or communication standard (e.g., VGA, DVI video, USB, RS-232, etc.), Wi-Fi connection, a Bluetooth connection, a cellular connection, an Ethernet connection, and so on.

In some embodiments, memory 728 can include any suitable storage device or devices that can be used to store instructions, values, data, or the like, that can be used, for example, by processor 722 to control the one or more image acquisition systems 724, and/or receive data from the one or more image acquisition systems 724; to images from data; present content (e.g., images, a user interface) using a display; communicate with one or more computing devices 650; and so on. Memory 728 can include any suitable volatile memory, non-volatile memory, storage, or any suitable combination thereof. For example, memory 728 can include RAM, ROM, EEPROM, one or more flash drives, one or more hard disks, one or more solid state drives, one or more optical drives, and so on. In some embodiments, memory 728 can have encoded thereon, or otherwise stored therein, a program for controlling operation of image source 602. In such embodiments, processor 722 can execute at least a portion of the program to generate images, transmit information and/or content (e.g., data, images) to one or more computing devices 650, receive information and/or content from one or more computing devices 650, receive instructions from one or more devices (e.g., a personal computer, a laptop computer, a tablet computer, a smartphone, etc.), and so on.

In some embodiments, any suitable computer readable media can be used for storing instructions for performing the functions and/or processes described herein. For example, in some embodiments, computer readable media can be transitory or non-transitory. For example, non-transitory computer readable media can include media such as magnetic media (e.g., hard disks, floppy disks), optical media (e.g., compact discs, digital video discs, Blu-ray discs), semiconductor media (e.g., random access memory (“RAM”), flash memory, electrically programmable read only memory (“EPROM”), electrically erasable programmable read only memory (“EEPROM”)), any suitable media that is not fleeting or devoid of any semblance of permanence during transmission, and/or any suitable tangible media. As another example, transitory computer readable media can include signals on networks, in wires, conductors, optical fibers, circuits, or any suitable media that is fleeting and devoid of any semblance of permanence during transmission, and/or any suitable intangible media.

The present disclosure has described one or more preferred embodiments, and it should be appreciated that many equivalents, alternatives, variations, and modifications, aside from those expressly stated, are possible and within the scope of the invention.

1. A computer-implemented method for identifying decreases in data quality during a magnetic resonance imaging (MRI) study, the method comprising:
receiving, by a computing system that includes at least one processor in communication with at least one memory system and that is in communication to receive data acquired using a magnetic resonance imaging (MRI) system, k-space data acquired by the MRI system while performing an MRI study;
analyzing, by the computing system, the received k-space data to identify signs of decreased data quality in the k-space data; and
displaying, by the computing system, a real-time indication to an operator of the MRI system during the MRI study, a report indicating the decreased data quality and at least one of an amount of k-space data affected by the decreased data quality or an amount of the MRI study to be repeated due to amount of k-space data affected by the decreased data quality.

2. The computer-implemented method of claim 1, wherein the computer system is further configured to predict a quantity of the k-space data that is affected by the decreased data quality using at least one of a learning network or artificial intelligence.

3. The computer-implemented method of claim 2, wherein the computing system is further configured to display the predicted quantity of the k-space data in real time as the subject is undergoing the MRI study.

4. The computer-implemented method of claim 1, wherein the computing system is further configured to identify signs of motion of the subject and to calculate an amount of motion of the subject by comparing the received k-space data to reference k-space data.

5. The computer-implemented method of claim 4, wherein comparing the received k-space data to reference k-space data includes minimizing the registration error for a transform, where the registration error is represented by:
$${ε}_{i} = 〈 {( sIi ( T ( x ) ) - {I}_{1} ( \vec{x} ) )}^{2} 〉$$
Where T represents a transform where i indexes the registration of dataset i to a k-space reference of dataset I, I(x) is an intensity at a locus x, and s is a scalar factor that compensates for fluctuations in mean signal intensity.

6. The computer-implemented method of claim 5, wherein a transform may be represented by a combination of rotations and displacements.

7. The computer-implemented method of claim 1, wherein the computing system is further configured to predict a quantity of the k-space data that is affected by the decreased data quality using a predetermined threshold for displacement.

8. The computer-implemented method of claim 7, wherein the displacement is determined using a plurality of displacement vectors of motion.

9. The computer-implemented method of claim 7, wherein displacement is determined as a rigid body by adding the absolute displacement in six directions, the motion of an I^{th} frame being represented as a scalar quantity by:
$$Displacement i = \vert {Ad}_{ix} \vert + \vert {Ad}_{iy} \vert + \vert {Ad}_{iz} \vert + \vert Acq \vert + \vert Δβ ; \vert + \vert Δγ ; \vert$$
where Δdᵢₓ=d_{(i_1)x}−dᵢₓ; Δd_{iy}=d_{(i_1)y}−d_{iy}; Δd_{iz}=d_{(i_1)z}−d_{iz}, dᵢ represents a vector of displacements, x, y, z, are translations in three coordinate axes, α, β, and γ are rotation angles, and Acq represents acquired k-space data.

10. The computer-implemented method of claim 1, wherein decreased data quality includes artifacts associated with at least one of respiration or head motion.

11. A computer-implemented method for identifying decreases in data quality during a magnetic resonance imaging (MRI) study, the method comprising:
receiving, by a computing system that includes at least one processor in communication with at least one memory system and that is in communication to receive data acquired using a magnetic resonance imaging (MRI) system, k-space data acquired by the MRI system while performing an MRI study;
analyzing, by the computing system, the received k-space data to identify signs of decreased data quality in the k-space data; and
displaying, by the computing system, a report indicating decreased data quality in the k-space data based on the analyzing of the received k-space data.

12. The computer-implemented method of claim 11, wherein the computer system is further configured to predict a quantity of the k-space data that is affected by the decreased data quality using at least one of a learning network or artificial intelligence.

13. The computer-implemented method of claim 12, wherein the computing system is further configured to display the predicted quantity of the k-space data in real time as the subject is undergoing the MRI study.

14. The computer-implemented method of claim 11, wherein the computing system is further configured to identify signs of motion of the subject and to calculate an amount of motion of the subject by comparing the received k-space data to reference k-space data.

15. The computer-implemented method of claim 14, wherein comparing the received k-space data to reference k-space data includes minimizing the registration error for a transform, where the registration error is represented by:
$${ε}_{i} = 〈 {( sIi ( T ( x ) ) - {I}_{1} ( \vec{x} ) )}^{2} 〉$$
Where T represents a transform where i indexes the registration of dataset i to a k-space reference of dataset I, I(x) is an intensity at a locus x, and s is a scalar factor that compensates for fluctuations in mean signal intensity.

16. The computer-implemented method of claim 15, wherein a transform may be represented by a combination of rotations and displacements.

17. The computer-implemented method of claim 11, wherein the computing system is further configured to predict a quantity of the k-space data that is affected by the decreased data quality using a predetermined threshold for displacement.

18. The computer-implemented method of claim 17, wherein the displacement is determined using a plurality of displacement vectors of motion.

19. The computer-implemented method of claim 17, wherein displacement is determined as a rigid body by adding the absolute displacement in six directions, the motion of an I^{th} frame being represented as a scalar quantity by:
$$Displacement i = \vert {Ad}_{ix} \vert + \vert {Ad}_{iy} \vert + \vert {Ad}_{iz} \vert + \vert Acq \vert + \vert Δβ ; \vert + \vert Δγ ; \vert$$
where Δdᵢₓ=d_{(i_1)x}−dᵢₓ; Δd_{iy}=d_{(i_1)y}−d_{iy}; Δd_{iz}=d_{(i_1)z}−d_{iz}, dᵢ represents a vector of displacements, x, y, z, are translations in three coordinate axes, α, β, and γ are rotation angles, and Acq represents acquired k-space data.

20. A magnetic resonance imaging system (MRI) configured for identifying decreases in data quality during a magnetic resonance imaging (MRI) study, the system comprising:
a computing system that includes at least one processor in communication with at least one memory system and that is in communication to receive k-space data acquired using the MRI system while performing an MRI study;
the computing system being configured to:
i) analyze the received k-space data to identify signs of decreased data quality in the k-space data; and
ii) display a real-time indication to an operator of the MRI system during the MRI study, a report indicating the decreased data quality and at least one of an amount of k-space data affected by the decreased data quality or an amount of the MRI study to be repeated due to amount of k-space data affected by the decreased data quality.
